(19) United States
(12) Patent Application Publication
(10) Pub. No.: US 2022/0084732 A1
(43) Pub. Date: Mar. 17, 2022

(54) PMSM Demagnetization Fault Diagnosis Method Based on Fuzzy Intelligent Learning of Torque Signals

(71) Applicant: Hunan University of Science and Technology, Xiangtan (CN)

(72) Inventors: Zhao-Hua Liu, Xiangtan (CN); Qi-Wei Xia, Xiangtan (CN); Chang-Tong Wang, Xiangtan (CN); Lei Chen, Xiangtan (CN); Zhu Zhang, Xiangtan (CN); Hong-Qiang Zhang, Xiangtan (CN); Xiao-Hua Li, Xiangtan (CN)

(21) Appl. No.: 17/355,639

(22) Filed: Jun. 23, 2021

(30) Foreign Application Priority Data
Sep. 15, 2020 (CN) 202010968338.1

(51) Int. Cl. H01F 13/00; G06N 20/00; G06N 3/04; G01R 31/34; H02P 29/032

(52) U.S. Cl. CPC H01F 13/006; G06N 20/00; H02P 29/032; G01R 31/34; G06N 3/0436

(57) ABSTRACT

A PMSM demagnetization fault diagnosis method based on fuzzy intelligent learning of torque signals, which includes the following steps of: acquiring torque ripple signals of permanent magnet synchronous motors under different demagnetization faults; calculating a fuzzy membership of the torque ripple signals; decomposing and reconstructing the torque ripple signals by using wavelet packet decomposition to obtain wavelet packet coefficients; calculating the energy of the wavelet packet coefficients, constructing a feature vector sample set with the fuzzy membership, and dividing it into a training set and a test set; constructing Fuzzy Extreme Learning Machine (FELM), and inputting the training set into the FELM for training; inputting the test set into the trained FELM, and calculating classification accuracy. The disclosure solves the problem of unbalanced and irregular training sample distribution by integrating fuzzy theory into the Extreme Learning Machine to fuzzify the torque ripple signal samples under demagnetization fault.

### CROSS REFERENCE TO RELATED APPLICATION(S)

This patent application claims the benefit and priority of Chinese Patent Application No. 202010968338.1 filed on Sep. 15, 2020, the disclosure of which is incorporated by reference herein in its entirety as part of the present application.

### TECHNICAL FIELD

The disclosure relates to the field of demagnetization fault diagnosis of Permanent Magnet Synchronous Motors, and in particular to a PMSM demagnetization fault diagnosis method based on fuzzy intelligent learning of torque signals.

### BACKGROUND ART

Permanent Magnet Synchronous Motor (PMSM) is widely applied in industrial and high-tech fields, such as high-speed railways, new energy vehicles and other fields, which has the advantages of wide speed range, high power density, precise torque control, etc. However, PMSM is prone to demagnetization faults in a complex working environment, which may cause torque pulsation, impair motor performance, and cause immeasurable losses to actual production. Therefore, the high-precision diagnosis of PMSM demagnetization faults plays a very important role in ensuring the normal production and life processes.

The torque ripple signals resulting from the PMSM demagnetization faults contain information on the demagnetization faults, which may be used to diagnose the demagnetization fault category. There exist three common PMSM demagnetization fault diagnosis methods: a signal processing-based method, a model and parameter identification-based method, and an artificial intelligence-based method. The signal processing-based method extracts the characteristics of the fault signals by using signal processing techniques such as Fourier Transform, Wavelet Transform, Empirical Mode Decomposition, and/or the like, which takes the information either at different scales or between time and frequency domains within the signals into account, whereby the accuracy of fault diagnosis can be improved. However, diagnosis methods based on signal processing may be susceptible to factors such as inverters, load fluctuations and the like, resulting in low accuracy of data samples. The model and parameter identification-based method may analyze the mechanism of faults by means of establishment of a precise mathematical model of the motor such that high-precision fault diagnosis may be conducted; however, the establishment of the precise mathematical model of the motor is often challenging and may be susceptible to the working environment, parameter variations, etc. In addition, it is even more challenging to establish specific mathematical models for different motors. Parameter identification of the motor's terminal voltage and electronic current through a method such as Kalman filtering enables estimation of the magnetic field conditions, which may improve the accuracy of diagnosis. But, this method cannot accurately identify uniform loss of magnetism and local loss of magnetism, and a Kalman Filter is unable to deal with the nonlinearity of data effectively. The fault diagnosis methods based on artificial intelligence have obtained rapid development. For example, Support Vector Machines, Automatic Encoders, and the like are widely used in the field of fault diagnosis, and have achieved high diagnostic accuracy. However, artificial intelligence algorithms also suffer from obvious shortcomings, such as great load of computation and difficulty in parameter optimization.

The level of PMSM demagnetization has imbalance and irregularity, and thus the sample distribution obtained also exhibits the characteristics of unevenness. If these samples are straightforwardly applied to the diagnosis models, the diagnosis results would be more inclined to labels with a larger number of samples. Fuzzy membership can indicate the tendency of the samples. By assigning a value between 0 and 1 to a sample, the difference in number of samples is regularized, whereby the problems of the difference in the number of samples in the training process can be effectively solved.

### SUMMARY

To solve the above technical problems, the disclosure provides a PMSM demagnetization fault diagnosis method based on fuzzy intelligent learning of torque signals, which is capable of achieving the high diagnosis accuracy with a simple algorithm.

The technical solution of the present disclosure for solving the above problems may be embodied in a PMSM demagnetization fault diagnosis method based on fuzzy intelligent learning of torque signals, which may include the following steps of:

(1) acquiring torque ripple signals of a Permanent Magnet Synchronous Motor (PMSM) under different demagnetization faults;

(2) calculating a fuzzy membership of all the torque ripple signals acquired;

(3) decomposing and reconstructing the acquired torque ripple signals by using wavelet packet decomposition to obtain a series of wavelet packet coefficients;

(4) calculating energy of the obtained wavelet packet coefficients, constructing a feature vector sample set with the fuzzy membership, and dividing the feature vector sample set into a training set and a test set;

(5) constructing a Fuzzy Extreme Learning Machine (FELM), and inputting the training set into the FELM for training; and

(6) inputting the test set into the trained FELM, and calculating classification accuracy.

According to the PMSM demagnetization fault diagnosis method based on fuzzy intelligent learning of torque signals as described above, in the step (1), the torque ripple signals are denoted as D={(x₁,t₁), (x₂,t₂), . . . , (x_{N},t_{N})}, where xᵢ represents an i-th torque ripple signal, tᵢ represents a demagnetization fault category corresponding to xᵢ, and is expressed as tᵢ=a, for a=1, 2 . . . A, where A is the number of fault categories, and for i=1, 2 . . . , N, where N is the number of samples of the torque signals.

According to the PMSM demagnetization fault diagnosis method based on fuzzy intelligent learning of torque signals as described above, in the step (2), the fuzzy membership refers to mapping of torque ripple signals under the different faults to a same interval of [0, 1] to indicate a tendency of the torque ripple signals; the step (2) may include the specific steps of:

(2-1) performing Fast Fourier Transform (FFT) separately on the torque ripple signals D under all faults to obtain a frequency spectrum of the torque signals;

(2-2) calculating the fuzzy membership S(x) of the torque signals according to the following formula:

$$S ( x ) = \frac{z {f}^{2}}{1 + z {f}^{2}} \qquad$$

where z is the reciprocal of the square of a mean value of values of spectral components of the torque ripple signals, and denoted as

$$z = 1 / {( ( {\sum }_{{J}^{= 1}}^{n} \overline{{f}_{j}} ) / n )}^{2} ,$$

ƒ̅ⱼ is a frequency value of a j-th frequency point on the spectrum, for j=1, 2, . . . , n, where n is the number of all frequency points on the spectrum; f is the frequency of the corresponding spectrum of the torque signals in different fault states, and is selected according to the following principles: selecting the highest value of a fundamental frequency for the signals in a normal state, and selecting the highest value of a high-frequency harmonic frequency for the signals in a demagnetization fault state;

(2-3) substituting f and z into a membership calculation formula to obtain the fuzzy membership of all the torque signals as:

S(x)=[S₁,S₂, . . . ,S_{N}]

where Sᵢ is the fuzzy membership corresponding to the i-th torque ripple signal, for i=1, 2, . . . , N; and

(2-4) normalizing all of the memberships:

$$\{ \begin{matrix}\overline{S} = {\sum }_{i = 1}^{N} {S}_{i} \\ S = [ \frac{{S}_{1}}{\overline{S}} , \frac{{S}_{2}}{\overline{S}} , … , \frac{{S}_{N}}{\overline{S}} ] = [ {s}_{1} , {s}_{2} , … , {s}_{N} ]\end{matrix}$$

where S̅ is the sum of the fuzzy membership of all the torque ripple signals, S is the normalized fuzzy membership, and sᵢ is the normalized fuzzy membership corresponding to the i-th torque ripple signal.

According to the PMSM demagnetization fault diagnosis method based on fuzzy intelligent learning of torque signals as described above, in the step (3), a wavelet packet decomposition recursive formula of a (r+1)-th layer may be expressed as follows:

$$\{ \begin{matrix}{d}_{r + 1}^{2 k} ( q ) = {\sum }_{m} h {d}_{r}^{k} ( m ) \\ {d}_{r + 1}^{2 k + 1} ( q ) = {\sum }_{m} g {d}_{r}^{k} ( m )\end{matrix}$$

where dᵣ₊₁^{2k}(q) represents a wavelet packet coefficient sequence of a (2k)-th subband of the (r+1)-th layer, dᵣ₊₁^{2k+1}(q) represents a wavelet packet coefficient sequence of a (2k+1)-th subband of the (r+1)-th layer, where q represents its length, dᵣ^{k}(m) represents a wavelet packet coefficient sequence of a k-th subband of an r-th layer, where m represents its length, and h and g represent a low-pass filter coefficient and a high-pass filter coefficient of the wavelet packet decomposition, respectively; and

a recursive formula of the wavelet packet reconstruction may be expressed as:

$${d}_{r}^{k} ( m ) = {\sum }_{q} \overline{h} {d}_{r + 1}^{2 k} ( q ) + {\sum }_{q} \overline{g} {d}_{r + 1}^{2 k + 1} ( q )$$

where h̅ and g̅ represent a low-pass filter coefficient and a high-pass filter coefficient of the wavelet packet reconstruction, respectively.

According to the PMSM demagnetization fault diagnosis method based on fuzzy intelligent learning of torque signals as described above, the step (4) may include the specific steps of:

(4-1) performing p-layer wavelet packet decomposition and reconstruction on the torque ripple signals, and performing energy calculation on an 1-th group of a p-th layer of the reconstructed wavelet packet coefficients:

$${E}_{p , l} = {\sum }_{b} {\vert {d}_{p}^{l} ( b ) \vert}^{2}$$

where E_{p,l} represents energy of the l-th group of the p-th layer of the reconstructed wavelet packet coefficients, dₚ^{l}(b) represents the wavelet packet coefficient sequence of an l-th subband of the p-th layer, and b represents the length of the wavelet packet coefficient sequence; and

a feature vector T of the torque ripple signals may then obtained as:

T=[E_{p,0},E_{p,1}, . . . ,E_{p,2}_{^{p}}₋₁]

(4-2) normalizing T:

$$\{ \begin{matrix}E = {\sum }_{l = 0}^{{2}^{p} - 1} {E}_{p , l} \\ \overline{T} = [ \frac{{E}_{p , 0}}{E} , \frac{{E}_{p , 1}}{E} , … , \frac{{E}_{p , {2}^{p} - 1}}{E} ]\end{matrix}$$

where E represents energy of the wavelet packet coefficients, T̅ represents a feature vector of the normalized torque ripple signals, the feature vector sample set with the fuzzy membership is denoted as {(T̅₁,t₁,s₁), (T̅₂,t₂,s₂), . . . , (T̅_{N},t_{N},s_{N})}, and T̅ᵢ is the sample of an i-th normalized feature vector; and

(4-3) dividing the feature vector sample set with the fuzzy membership into the training set and the test set.

According to the PMSM demagnetization fault diagnosis method based on fuzzy intelligent learning of torque signals as described above, in the step (5), the Fuzzy Extreme Learning Machine (FELM) may be constructed by integrating a fuzzy theory into an Extreme Learning Machine (ELM) to fuzzify input samples, and a specific process of constructing the Fuzzy Extreme Learning Machine (FELM) may include operations as below:

(5-1) for a single-hidden-layer feedforward neural network with u input nodes, L hidden layer nodes, and v output layer nodes, assuming that there are M samples) {(X₁,Y₁), (X₂,Y₂), . . . , (X_{M},Y_{M})}, X_{τ} is the τ-th sample, Y_{τ} is a label corresponding to the sample X_{τ}, for τ=1, 2, . . . , M, and an output y_{τ} of the τ-th sample of the neural network is calculated by:

$${y}_{τ} = {\sum }_{μ = 1}^{L} {β}_{μ} G ( {W}_{μ} \cdot {X}_{τ} + {b}_{μ} )$$

where β_{μ} is an weight vector from neurons of a μ-th hidden layer to an output layer, W_{μ} is an weight vector from an input layer to neurons of the μ-th hidden layer, b_{μ} is a bias of neurons of the μ-th hidden layer, for μ=1, 2, . . . , L, G is an activation function, and W_{μ}·X_{τ} represents an inner product of W_{μ} and X_{τ};

(5-2) for each sample X_{τ}, minimizing an output error of the network, namely:

$${\sum }_{μ = 1}^{L} {β}_{μ} G ( {W}_{μ} \cdot {X}_{τ} + {b}_{μ} ) - {Y}_{τ} = 0$$

and therefore, to minimize a total output error, expressing an objective function of the neural network as:

$$ℒ = {\sum }_{τ = 1}^{M} ( {\sum }_{μ = 1}^{L} {β}_{μ} G ( {W}_{μ} \cdot {X}_{τ} + {b}_{μ} ) - {Y}_{τ} )$$

(5-3) transforming the above formula into:

Hβ=O

where H is an output matrix of an hidden layer, β is a weight matrix from the hidden layer to the output layer, and O is an expected output, and:

$$H = ( \begin{matrix}G ( {W}_{1} \cdot {X}_{1} + {b}_{1} ) & G ( {W}_{2} \cdot {X}_{1} + {b}_{2} ) & … & G ( {W}_{L} \cdot {X}_{1} + {b}_{L} ) \\ G ( {W}_{1} \cdot {X}_{2} + {b}_{1} ) & G ( {W}_{2} \cdot {X}_{2} + {b}_{2} ) & … & G ( {W}_{L} \cdot {X}_{2} + {b}_{L} ) \\ ⋮ & ⋮ & ⋮ & ⋮ \\ G ( {W}_{1} \cdot {X}_{M} + {b}_{1} ) & G ( {W}_{2} \cdot {X}_{M} + {b}_{2} ) & … & G ( {W}_{L} \cdot {X}_{M} + {b}_{L} )\end{matrix} ) , \\ β = ( \begin{matrix}{β}_{1}^{′} \\ {β}_{2}^{′} \\ ⋮ \\ {β}_{L}^{′}\end{matrix} ) , O = ( \begin{matrix}{O}_{1}^{′} \\ {O}_{2}^{′} \\ ⋮ \\ {O}_{M}^{′}\end{matrix} ) ;$$

where β′_{L} represents a transposed matrix of β_{L}, and y′_{M} represents a transposed matrix of y_{M};

(5-4) since W_{μ} and b_{μ} are randomly initialized and fixed by ELM, determining uniquely an optimal solution \hat{β} of β as:

\hat{β}=H⁺O

where H⁺ is a generalized inverse of H;

(5-5) solving the above formula to obtain:

$$\hat{β} = {{H}^{′} ( \frac{1}{C} + H {H}^{′} )}^{- 1} O$$

where H′ represents a transposed matrix of H, and C represents a penalty factor; and

(5-6) determining the β solution goal after fuzzy theory integration as:

$$\hat{β} = {{H}^{′} ( \frac{S}{C} + H {H}^{′} )}^{- 1} O .$$

According to the PMSM demagnetization fault diagnosis method based on fuzzy intelligent learning of torque signals as described above, in the step (6), the classification accuracy may be defined as:

$$C A = \frac{{\sum }_{ρ = 1}^{P} ( {\hat{t}}_{ρ} == {t}_{ρ} )}{P}$$

where \hat{t}_{ρ} is a label predicted from a ρ-th sample x_{ρ} when the FELM performs fault diagnosis, t_{ρ} is a true label of x_{ρ}, for ρ=1, 2, . . . , P, wherein P is the total number of diagnostic samples; when \hat{t}_{ρ} is equal to t_{ρ}, \hat{t}_{ρ}==t_{ρ} is 1; when t_{ρ} is not equal to t_{ρ}, \hat{t}_{ρ}==t_{ρ} is 0; and

$${\sum }_{ρ = 1}^{P} ( {\hat{t}}_{ρ} == {t}_{ρ} )$$

is the number of correct diagnosis.

The beneficial effects of the disclosure may include the following points.

1. According to the disclosure, the Fuzzy Theory is fused into the Extreme Learning Machine to fuzzify the torque pulsation signal samples under demagnetization fault, whereby the problems of unbalanced and irregular of training sample distribution may be solved, and the conventional machine learning algorithms may adapt to the torque signals under demagnetization fault. As a result, the training may be speed up, and the diagnosis accuracy may be improved.

2. According to the disclosure, wavelet packet decomposition is employed to decompose the torque ripple signals layer by layer to obtain a series of wavelet packet decomposition coefficients. Moreover, the energy values of these coefficients may be calculated such that the originally complex and noise-containing torque pulsation signals may be converted into energy feature samples, thereby eliminating the influence of noise and extracting the features contained in the torque signals.

### BRIEF DESCRIPTION OF THE DRAWINGS

FIG. 1 shows a flow chart of the disclosure.

FIG. 2 shows a schematic diagram of three-layer wavelet packet decomposition.

FIG. 3 shows a schematic diagram of an ELM structure.

FIG. 4 shows a histogram of a comparative experiment of the disclosure.

### DETAILED DESCRIPTION OF THE EMBODIMENTS

The disclosure will be further described below in conjunction with the drawings and embodiments.

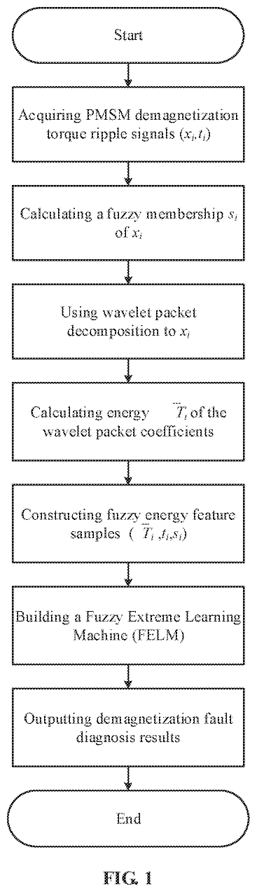

As shown in FIG. 1, a PMSM demagnetization fault diagnosis method based on fuzzy intelligent learning of torque signals may include the following steps.

(1) Acquiring torque ripple signals of Permanent Magnet Synchronous Motor (PMSM) under different demagnetization faults.

Torque ripple signals are denoted as D={(x₁,t₁), (x₂,t₂), . . . , (x_{N},t_{N})}, where xᵢ represents the i-th torque ripple signal, tᵢ represents the demagnetization fault category corresponding to xᵢ, and is expressed as tᵢ=a, for a=1, 2 . . . A, where A is the number of fault categories, and for i=1, 2 . . . , N, where N is the number of samples of the torque signal.

(2) Calculating fuzzy membership of all of the torque ripple signals acquired.

The fuzzy membership means mapping of the torque ripple signals of different faults to the same interval of [0, 1] to express the tendency of the torque ripple signals. The step (2) may include the specific steps as follows.

(2-1) Performing Fast Fourier Transform (FFT) separately on the torque pulsation signals under all fault to obtain the frequency spectrum of the torque signals.

(2-2) Calculating the fuzzy membership S(x) of the torque signals according to the following formula:

$$S ( x ) = \frac{z {f}^{2}}{1 + z {f}^{2}} \qquad$$

where z is the reciprocal of the square of the mean value of values of the spectral components of the torque ripple signals, and denoted as

$$z = 1 / {( ( {\sum }_{{ }^{j = 1}}^{n} \overline{{f}_{j}} ) / n )}^{2} ,$$

ƒⱼ is the frequency value of the j-th frequency point on the spectrum, for j=1, 2, . . . , n, where n is the number of all frequency points on the spectrum, f is the frequency of the corresponding frequency spectrum of the torque signals in different fault states, and may be selected according to the following principles: selecting the highest value of the fundamental frequency for the signals in a normal state, and selecting the highest value of the high-frequency harmonic frequency for the signals in a demagnetization fault state.

(2-3) Substituting f and z into the membership calculation formula to obtain the fuzzy membership of all the torque signals as:

S(x)=[S₁,S₂, . . . ,S_{N}]

where Sᵢ is the fuzzy membership corresponding to the i-th torque ripple signal, for i=1, 2, . . . , N.

(2-4) Normalizing all of the memberships:

$$\{ \begin{matrix}\overline{S} = {\sum }_{i = 1}^{N} {S}_{i} \\ S = [ \frac{{S}_{1}}{\overline{S}} , \frac{{S}_{2}}{\overline{S}} , … , \frac{{S}_{N}}{\overline{S}} ] = [ {s}_{1} , {s}_{2} , … , {s}_{N} ]\end{matrix}$$

where S̅ is the sum of the fuzzy membership of all the torque ripple signals, S is the normalized fuzzy membership, and sᵢ is the normalized fuzzy membership corresponding to the i-th torque ripple signal.

(3) Decomposing and reconstructing the acquired torque ripple signals by using wavelet packet decomposition to obtain a series of wavelet packet coefficients.

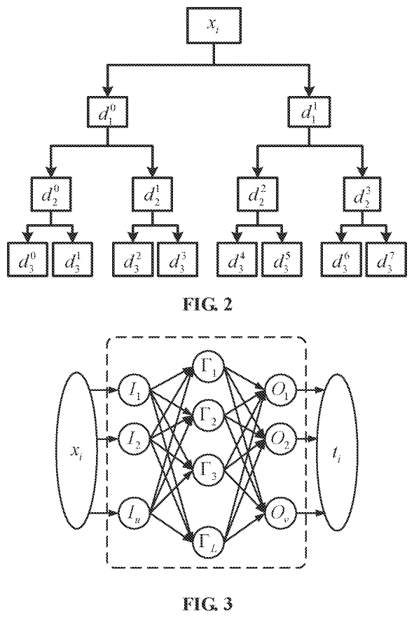

FIG. 2 shows a schematic diagram of three-layer wavelet packet decomposition. The recursive formula for the decomposition of the (r+1)-th layer of wavelet packet may be expressed as follows:

$$\{ \begin{matrix}{d}_{r + 1}^{2 k} ( q ) = {\sum }_{m} h {d}_{r}^{k} ( m ) \\ {d}_{r + 1}^{2 k + 1} ( q ) = {\sum }_{m} g {d}_{r}^{k} ( m )\end{matrix}$$

where dᵣ₊₁^{2k}(q) represents the wavelet packet coefficient sequence of the (2k)-th subband of the (r+1)-th layer, dᵣ₊₁^{2k+1}(q) represents the wavelet packet coefficient sequence of the (2k+1)-th subband of the (r+1)-th layer, where q represents its length, dᵣ^{k}(m) represents the wavelet packet coefficient sequence of the k-th subband of the r-th layer, where m represents its length, and h and g represent the low-pass filter coefficient and the high-pass filter coefficient of wavelet packet decompositions, respectively.

The recursive formula of wavelet packet reconstruction may be expressed as:

$${d}_{r}^{k} ( m ) = {\sum }_{q} \overline{h} {d}_{r + 1}^{2 k} ( q ) + {\sum }_{q} \overline{g} {d}_{r + 1}^{2 k + 1} ( q )$$

where h̅ and g̅ are the low-pass filter coefficient and the high-pass filter coefficient of wavelet packet reconstruction, respectively.

(4) Calculating the energy of the wavelet packet coefficients, constructing a feature vector sample set with fuzzy membership, and dividing it into a training set and a test set. The step (4) may include the specific steps as follows.

(4-1) Performing p-layer wavelet packet decomposition and reconstruction on the torque ripple signals, and performing energy calculation on the l-th group of the p-th layer of the reconstructed wavelet packet coefficients:

$${E}_{p , l} = {\sum }_{b} {\vert {d}_{p}^{l} ( b ) \vert}^{2}$$

where E_{p,l} represents the energy of the l-th group of the p-th layer of the reconstructed wavelet packet coefficients, dₚ^{l}(b) represents the wavelet packet coefficient sequence of the l-th subband of the p-th layer, and b represents the length of the wavelet packet coefficient sequence;

and then the feature vector T of the torque ripple signals may be obtained as:

T=[E_{p,0},E_{p,1}, . . . ,E_{p,2}_{^{p}}₋₁]

(4-2) Normalizing T:

$$\{ \begin{matrix}E = {\sum }_{l = 0}^{{2}^{p} - 1} {E}_{p , l} \\ \overline{T} = [ \frac{{E}_{p , 0}}{E} , \frac{{E}_{p , 1}}{E} , … , \frac{{E}_{p , {2}^{p} - 1}}{E} ]\end{matrix}$$

where E represents energy of the wavelet packet coefficients, T̅ represents a feature vector of the normalized torque ripple signals, the feature vector sample set with the fuzzy membership is denoted as {(T̅₁,t₁,s₁), (T̅₂,t₂,s₂), . . . , (T̅_{N},t_{N},s_{N})}, and T̅ᵢ is the sample of an i-th normalized feature vector; and

(4-3) Dividing the feature vector sample set with the fuzzy membership into the training set and the test set.

(5) Constructing a Fuzzy Extreme Learning Machine (FELM), and inputting the training set into the FELM for training.

The Fuzzy Extreme Learning Machine (FELM) may be constructed by integrating fuzzy theory into the Extreme Learning Machine (ELM) to fuzzify the input samples. The ELM may be a single-hidden-layer feedforward neural network, as illustrated in FIG. 3. Traditional single-hidden-layer neural networks need to be solved by employing algorithms such as Gradient Descent, and thus a large number of iterations are required to update all weights and thresholds, which are time consuming and often fall into local minimums. For the traditional single-hidden-layer feedforward neural network, the FELM randomly generates the weights from the input layer to the hidden layer and the thresholds of the hidden layer, which remain unchanged during the training process. The unique optimal solution can be obtained by setting only the number of neurons in the hidden layer.

The specific process of constructing the Fuzzy Extreme Learning Machine (FELM) is described below.

(5-1) for a single-hidden-layer feedforward neural network with u input nodes, L hidden layer nodes, and v output layer nodes, assuming that there are M samples {(X₁,Y₁)(X₂,Y₂), . . . (X_{M},Y_{M})}, X_{τ} is the τ-th sample, Y_{τ} is a label corresponding to the sample X_{τ}, for τ=1, 2, . . . , M, and an output y_{τ} of the τ-th sample of the neural network is calculated by:

$${y}_{τ} = {\sum }_{μ = 1}^{L} {β}_{μ} G ( {W}_{μ} \cdot {X}_{τ} + {b}_{μ} )$$

where β_{μ} is an weight vector from neurons of a μ-th hidden layer to an output layer, W_{μ} is an weight vector from an input layer to neurons of the μ-th hidden layer, b_{μ} is a bias of neurons of the μ-th hidden layer, for μ=1, 2, . . . , L, G is an activation function, and W_{μ}·X_{τ} represents an inner product of W_{μ} and X_{τ};

(5-2) For each sample X_{τ}, minimizing the output error of the network, namely:

$${\sum }_{μ = 1}^{L} {β}_{μ} G ( {W}_{μ} \cdot {X}_{τ} + {b}_{μ} ) - {Y}_{τ} = 0$$

and therefore, in order to minimize the total output error, the objective function of the neural network may be expressed as:

$$ℒ = {\sum }_{τ = 1}^{M} ( {\sum }_{μ = 1}^{L} {β}_{μ} G ( {W}_{μ} \cdot {X}_{τ} + {b}_{μ} ) - {Y}_{τ} ) .$$

(5-3) Transforming the above formula into:

Hβ=O

where H is the output matrix of the hidden layer, β is the weight matrix from the hidden layer to the output layer, and O is the expected output, and:

$$H = ( \begin{matrix}G ( {W}_{1} \cdot {X}_{1} + {b}_{1} ) & G ( {W}_{2} \cdot {X}_{1} + {b}_{2} ) & … & G ( {W}_{L} \cdot {X}_{1} + {b}_{L} ) \\ G ( {W}_{1} \cdot {X}_{2} + {b}_{1} ) & G ( {W}_{2} \cdot {X}_{2} + {b}_{2} ) & … & G ( {W}_{L} \cdot {X}_{2} + {b}_{L} ) \\ ⋮ & ⋮ & ⋮ & ⋮ \\ G ( {W}_{1} \cdot {X}_{M} + {b}_{1} ) & G ( {W}_{2} \cdot {X}_{M} + {b}_{2} ) & … & G ( {W}_{L} \cdot {X}_{M} + {b}_{L} )\end{matrix} ) , \\ β = ( \begin{matrix}{β}_{1}^{′} \\ {β}_{2}^{′} \\ ⋮ \\ {β}_{L}^{′}\end{matrix} ) , O = ( \begin{matrix}{y}_{1}^{′} \\ {y}_{2}^{′} \\ ⋮ \\ {y}_{L}^{′}\end{matrix} ) ;$$

where β′_{L} represents a transposed matrix of β_{L}, and y′_{M} represents a transposed matrix of y_{M}.

(5-4) since W_{μ} and b_{μ} are randomly initialized and fixed by ELM, determining uniquely an optimal solution \hat{β} of β as:

\hat{β}=H⁺O

where H⁺ is a generalized inverse of H.

(5-5) Solving the above formulae to obtain:

$$\hat{β} = {{H}^{′} ( \frac{1}{C} + H {H}^{′} )}^{- 1} O$$

where H′ represents a transposed matrix of H, and C represents a penalty factor.

(5-6) Determining the β solution goal after Fuzzy Theory integration as:

$$\hat{β} = {{H}^{′} ( \frac{S}{C} + H {H}^{′} )}^{- 1} O .$$

(6) Inputting the test set into the trained FELM, and calculating the classification accuracy.

The classification accuracy CA may be defined as:

$$C A = \frac{{\sum }_{ρ = 1}^{P} ( {\hat{t}}_{ρ} = = {t}_{ρ} )}{P}$$

where \hat{t}_{ρ}, is the label predicted from the ρ-th sample x_{ρ} when FELM is used to perform fault diagnosis, t_{ρ} is the true label of x_{ρ}, for ρ=1, 2, . . . , P, where P is the total number of diagnostic samples; when \hat{t}_{ρ} is equal to t_{ρ}, \hat{t}_{ρ}==t_{ρ} is 1; when \hat{t}_{ρ} is not equal to t_{ρ}, \hat{t}_{ρ}==t_{ρ} is 0; and

$${\sum }_{ρ = 1}^{P} ( {\hat{t}}_{ρ} = = {t}_{ρ} )$$

represents the number of correct diagnoses.

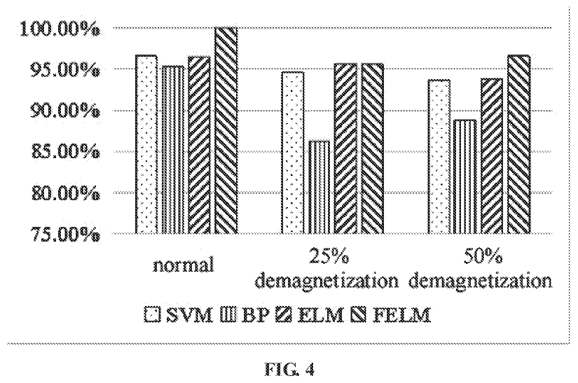

In order to verify the effectiveness of the disclosure, three types of diagnostic methods including Support Vector Machine (SVM), BP Neural Network and ELM are selected for comparison tests. The fault torque pulsation signals at the rated speed of the PMSM may be selected as the test data. The degree of fault demagnetization may include normal state, 25% demagnetization and 50% demagnetization, and the respective fuzzy memberships are calculated. The torque signals may be decomposed in three layers through the wavelet packet decomposition, and eight wavelet packet decomposition coefficients of each torque signal sample are obtained, and the calculation may be performed to obtain energy feature sets. These feature sets are used in the diagnosis method to obtain the diagnosis accuracy. The experimental results are illustrated in FIG. 4, and it demonstrates that the PMSM demagnetization fault diagnosis accuracy of the method proposed in the disclosure is higher than other methods.

To sum up, the PMSM demagnetization fault diagnosis method based on fuzzy intelligent learning of torque signals of the disclosure combines Fuzzy Theory with an Extreme Learning Machine, and is capable of solving the problems of imbalance and irregularity of samples by calculating the membership of the PMSM demagnetization fault torque signals, thereby speeding up the diagnosis process. Subsequently, the energy features of the samples are extracted through wavelet packet decomposition and reconstruction, which improves the accuracy of demagnetization fault diagnosis.

What is claimed is:

1. A PMSM demagnetization fault diagnosis method based on fuzzy intelligent learning of torque signals, comprising the following steps of:
(1) acquiring torque ripple signals of a Permanent Magnet Synchronous Motor (PMSM) under different demagnetization faults;
(2) calculating a fuzzy membership of all the torque ripple signals acquired;
(3) decomposing and reconstructing the acquired torque ripple signals by using wavelet packet decomposition to obtain a series of wavelet packet coefficients;
(4) calculating energy of the obtained wavelet packet coefficients, constructing a feature vector sample set with the fuzzy membership, and dividing the feature vector sample set into a training set and a test set;
(5) constructing a Fuzzy Extreme Learning Machine (FELM), and inputting the training set into the FELM for training; and
(6) inputting the test set into the trained FELM, and calculating classification accuracy.

2. The PMSM demagnetization fault diagnosis method based on fuzzy intelligent learning of torque signals according to claim 1, wherein in the step (1), the torque ripple signals are denoted as D={(x₁,t₁)(x₂,t₂), . . . , (x_{N},t_{N})} wherein xᵢ represents an i-th torque ripple signal, tᵢ represents a demagnetization fault category corresponding to xᵢ, and is expressed as tᵢ=a, for a=1, 2 . . . A, wherein A is the number of fault categories, and for i=1, 2 . . . N, wherein N is the number of samples of the torque signals.

3. The PMSM demagnetization fault diagnosis method based on fuzzy intelligent learning of torque signals according to claim 2, wherein in the step (2), the fuzzy membership refers to mapping of torque ripple signals under the different faults to a same interval of [0, 1] to indicate a tendency of the torque ripple signals; the step (2) comprises the specific steps of:
(2-1) performing Fast Fourier Transform (FFT) separately on the torque ripple signals D under all faults to obtain a frequency spectrum of the torque signals;
(2-2) calculating the fuzzy membership S(x) of the torque signals according to the following formula:
$$S ( x ) = \frac{z {f}^{2}}{1 + z {f}^{2}} \qquad$$
where z is the reciprocal of the square of a mean value of values of spectral components of the torque ripple signals, and denoted as
$$z = 1 / {( ( {\sum }_{j = 1}^{n} \overline{{f}_{j}} ) / n )}^{2} ,$$
ƒ̅ⱼ is a frequency value of a j-th frequency point on the spectrum, for j=1, 2, . . . , n, wherein n is the number of all frequency points on the spectrum; f is the frequency of the corresponding spectrum of the torque signals in different fault states, and is selected according to the following principles: selecting the highest value of a fundamental frequency for the signals in a normal state, and selecting the highest value of a high-frequency harmonic frequency for the signals in a demagnetization fault state;
(2-3) substituting f and z into a membership calculation formula to obtain the fuzzy membership of all the torque signals as:
S(x)=[S₁,S₂, . . . ,S_{N}]
where Sᵢ is the fuzzy membership corresponding to the i-th torque ripple signal, for i=1, 2, . . . , N; and
(2-4) normalizing all of the memberships:
$$\{ \begin{matrix}\overline{S} = {\sum }_{i = 1}^{N} {S}_{i} \\ S = [ \frac{{S}_{1}}{\overline{S}} , \frac{{S}_{2}}{\overline{S}} , … , \frac{{S}_{N}}{\overline{S}} , ] = [ {s}_{1} {s}_{2} , … , {s}_{N} ]\end{matrix}$$
where S̅ is the sum of the fuzzy membership of all the torque ripple signals, S is the normalized fuzzy membership, and sᵢ is the normalized fuzzy membership corresponding to the i-th torque ripple signal.

4. The PMSM demagnetization fault diagnosis method based on fuzzy intelligent learning of torque signals according to claim 3, wherein in the step (3), a wavelet packet decomposition recursive formula of a (4-1)-th layer is expressed as follows:
$$\{ \begin{matrix}{d}_{r + 1}^{2 k} ( q ) = {\sum }_{m} h {d}_{r}^{k} ( m ) \\ {d}_{r + 1}^{2 k + 1} ( q ) = {\sum }_{m} g {d}_{r}^{k} ( m )\end{matrix}$$
where dᵣ₊₁^{2k}(q) represents a wavelet packet coefficient sequence of a (2k)-th subband of the (r+1)-th layer, dᵣ₊₁^{2k+1}(q) represents a wavelet packet coefficient sequence of a (2k+1)-th subband of the (r+1)-th layer, wherein q represents its length, dᵣ^{k}(m) represents a wavelet packet coefficient sequence of a k-th subband of an r-th layer, wherein m represents its length, and h and g represent a low-pass filter coefficient and a high-pass filter coefficient of the wavelet packet decomposition, respectively; and
a recursive formula of the wavelet packet reconstruction is expressed as:
$${d}_{r}^{k} ( m ) = {\sum }_{q} \overline{h } {d}_{r + 1}^{2 k} ( q ) + {\sum }_{q} \overline{g } {d}_{r + 1}^{2 k} ( q )$$
where h̅ and g̅ represent a low-pass filter coefficient and a high-pass filter coefficient of the wavelet packet reconstruction, respectively.

5. The PMSM demagnetization fault diagnosis method based on fuzzy intelligent learning of torque signals according to claim 4, wherein the step (4) includes the specific steps of:
(4-1) performing, p-layer wavelet packet decomposition and reconstruction on the torque ripple signals, and performing energy calculation on an l-th group of a p-th layer of the reconstructed wavelet packet coefficients:
$${E}_{p , l} = {\sum }_{b} {\vert {d}_{p}^{l} ( b ) \vert}^{2}$$
where E_{p,l} represents energy of the l-th group of the p-th layer of the reconstructed wavelet packet coefficients, dₚ^{l}(b) represents the wavelet packet coefficient sequence of an l-th subband of the p-th layer, and b represents the length of the wavelet packet coefficient sequence, and
a feature vector T of the torque ripple signals is then obtained as:
T=[E_{p,0},E_{p,1}, . . . ,E_{p,2}_{^{p}}₋₁]
(4-2) normalizing T:
$$\{ \begin{matrix}E = {\sum }_{l = 0}^{{2}^{p} - 1} {E}_{p , l} \\ \overline{T} = [ \frac{{E}_{p , 0}}{E} , \frac{{E}_{p , 2}}{E} , … , \frac{{E}_{p , {2}^{p} - 1}}{E} ]\end{matrix}$$
where E represents energy of the wavelet packet coefficients, T̅ represents a feature vector of the normalized torque ripple signals, the feature vector sample set with the fuzzy membership is denoted as {(T̅₁,t₁,s₁), (T̅₂,t₂,s₂), . . . , (T̅_{N},t_{N},s_{N})}, and T̅ᵢ is the sample of an i-th normalized feature vector; and
(4-3) dividing the feature vector sample set with the fuzzy membership into the training set and the test set.

6. The PMSM demagnetization fault diagnosis method based on fuzzy intelligent learning of torque signals according to claim 5, wherein in the step (5), the Fuzzy Extreme Learning Machine (FELM) is constructed by integrating a fuzzy theory into an Extreme Learning Machine (ELM) to fuzzify input samples, and a specific process of constructing the Fuzzy Extreme Learning Machine (FELM) comprises:
(5-1) for a single-hidden-layer feedforward neural network with u input nodes, L hidden layer nodes, and v output layer nodes, assuming that there are M samples {(X₁,Y₁), (X₂,Y₂), . . . , (X_{M},Y_{M})}, X_{τ} is the τ-th sample, Y_{τ} is a label corresponding to the sample X_{τ}, for τ=1, 2, . . . , M, and an output y_{τ} of the τ-th sample of the neural network is calculated by:
$${y}_{τ} = {\sum }_{μ = 1}^{L} {β}_{μ} G ( {W}_{μ} \cdot {X}_{τ} + {b}_{μ} )$$
where β_{μ} is an weight vector from neurons of a μ-th hidden layer to an output layer, W_{μ} is an weight vector from an input layer to neurons of the μ-th hidden layer, b_{μ} is a bias of neurons of the μ-th hidden layer, for μ=1, 2, . . . , L, G is an activation function, and W_{μ}·X_{τ} represents an inner product of W_{μ} and X_{τ};
(5-2) for each sample X_{τ}, minimizing an output error of the network, namely:
$${\sum }_{μ = 1}^{L} {β}_{μ} G ( {W}_{μ} \cdot {X}_{τ} + {b}_{μ} ) - {Y}_{τ} = 0$$
and therefore, to minimize a total output error, expressing an objective function of the neural network as:
$$ℒ = {\sum }_{τ = 1}^{M} ( {\sum }_{μ = 1}^{L} {β}_{μ} G ( {W}_{μ} \cdot {X}_{τ} + {b}_{μ} ) - {Y}_{τ} )$$
(5-3) transforming the above formula into:
Hβ=O
where H is an output matrix of an hidden layer, β is a weight matrix from the hidden layer to the output layer, and O is an expected output, and:
$$H = ( \begin{matrix}G ( {W}_{1} \cdot {X}_{1} + {b}_{1} ) & G ( {W}_{2} \cdot {X}_{1} + {b}_{2} ) & … & G ( {W}_{L} \cdot {X}_{1} + {b}_{L} ) \\ G ( {W}_{1} \cdot {X}_{2} + {b}_{1} ) & G ( {W}_{2} \cdot {X}_{2} + {b}_{2} ) & … & G ( {W}_{L} \cdot {X}_{2} + {b}_{L} ) \\ ⋮ & ⋮ & ⋮ & ⋮ \\ G ( {W}_{1} \cdot {X}_{M} + {b}_{1} ) & G ( {W}_{2} \cdot {X}_{M} + {b}_{2} ) & … & G ( {W}_{L} \cdot {X}_{M} + {b}_{L} )\end{matrix} ) , \\ β = ( \begin{matrix}{β}_{1}^{′} \\ {β}_{2}^{′} \\ ⋮ \\ {β}_{L}^{′}\end{matrix} ) , O = ( \begin{matrix}{y}_{1}^{′} \\ {y}_{2}^{′} \\ ⋮ \\ {y}_{M}^{′}\end{matrix} ) ;$$
where β′_{L}, represents a transposed matrix of β_{L}, and y′_{M} represents a transposed matrix of y_{M};
(5-4) since W_{μ} and b_{μ} are randomly initialized and fixed by ELM, determining uniquely an optimal solution \hat{β} of β as:
\hat{β}=H⁺O
where H⁺ is a generalized inverse of H;
(5-5) solving the above formula to obtain:
$$\hat{β} = {{H}^{′} ( \frac{1}{C} + H {H}^{′} )}^{- 1} O$$
where H′ represents a transposed matrix of H, and C represents a penalty factor; and
(5-6) determining the β solution goal after fuzzy theory integration as:
$$\hat{β} = {{H}^{′} ( \frac{S}{C} + H {H}^{′} )}^{- 1} O .$$

7. The PMSM demagnetization fault diagnosis method based on fuzzy intelligent learning of torque signals according to claim 6, wherein in the step (6), the classification accuracy is defined as:
$$C A = \frac{{\sum }_{ρ = 1}^{P} ( {\hat{t}}_{ρ} == {t}_{ρ} )}{P}$$
where \hat{t}_{ρ} is a label predicted from a ρ-th sample x_{ρ} when the FELM performs fault diagnosis, t_{ρ} is a true label of x_{ρ}, for ρ=1, 2, . . . , P, wherein P is the total number of diagnostic samples; when \hat{t}_{ρ} is equal to t_{ρ}, \hat{t}_{ρ}==t_{ρ} is 1; when t_{ρ} is not equal to t_{ρ}, \hat{t}_{ρ}==t_{ρ} is 0; and
$${\sum }_{ρ = 1}^{P} ( {\hat{t}}_{ρ} == {t}_{ρ} )$$
is the number of correct diagnosis.
